(19) United States
(12) Patent Application Publication
(10) Pub. No.: US 2007/0020933 A1
(43) Pub. Date: Jan. 25, 2007

(54) Method of cleaning treatment and method for manufacturing semiconductor device

(76) Inventor: Koichi Naniwae, Tokyo (JP)

Correspondence Address: YOUNG & THOMPSON, 745 SOUTH 23RD STREET, 2ND FLOOR, ARLINGTON, VA, 22202, US

(21) Appl. No.: 10/573,492

(22) PCT Filed: Sep. 24, 2003
(86) PCT No.: PCT/JP03/12146

§ 371 Date: May 15, 2006

(51) Int. Cl. H01L 21/302

(52) U.S. Cl. 438/689

(57) ABSTRACT

In a crystal growth reactor, a source material having an etching action and a crystal growth source material are simultaneously supplied to a semiconductor wafer surface, so that residual impurities can be eliminated in an efficient manner by balancing etching rate and crystal growth rate.

### TECHNICAL FIELD

The present invention relates to technology for cleaning the surface of a semiconductor layer.

### BACKGROUND ART

In processes for manufacturing a semiconductor device, situations where a step of growing crystal of a semiconductor layer of the same species or different species on a semiconductor substrate, a step of patterning using photolithography taking a dielectric body etc. as a mask and performing chemical etching or dry etching, and a step of regrowing a semiconductor layer of the same species or a different species in order to bring about a current block structure or an optical confinement structure are repeated are common. In this event, the substrate surface prior to crystal growth and the semiconductor growth layer surface prior to regrowth are easily subjected to contamination with impurities and physical damage due to processes such as exposure to the atmosphere, etching, and cleaning, etc. so that if crystal growth is carried out with these surfaces as is, device characteristics and lifespan may substantially deteriorate. Because of this, in order to eliminate impurity contamination and physically damaged layers, techniques are employed where etching is carried out within a crystal growth chamber and crystal growth is then continued.

With this kind of technology, in U.S. Pat. No. 3,158,651, impurities such as carbon (C), oxygen (O), and silicon (Si) etc. can be eliminated by implementing etching within a growth chamber directly before regrowth of GaAs using trimethylgalium (TMG) and arsine (AsH₃) as a growth source material and using hydrogen chloride (HCl) as an etching material. By then supplying HCl and TMG during etching, shifts from stoichiometry occurring at the crystal surface due to etching are compensated, and the accumulation of carriers at the regrowth interface can be suppressed.

Further, in Japanese Patent Laid-open Publication No. Sho. 59-65434, with vapor phase epitaxy of a GaAs semiconductor, technology is disclosed for etching a semiconductor layer while simultaneously introducing an alkyl compound of a group III element and a hydride of a group V element together with hydrogen chloride. An example of an etching rate of 0.1 μm every minute is shown as an etching rate. As a result of doing this, it is possible for a foundation surface prior to the start of growth to be made a mirror finished surface.

Further, in Japanese Patent Laid-open Publication No. Sho. 51-74580, technology is disclosed where gaseous phase etching of semi-conducting material composed of elements of groups III-V is implemented in an inert gas atmosphere containing halides and hyrdrides of group V elements, while hydrides of group V elements are simultaneously introduced. According to the same publication, it is disclosed that it is possible to obtain a substrate surface that is flat with a superior mirror finished surface.

Further, on the other hand, as disclosed in U.S. Pat. No. 3,339,486, technology is disclosed where, with an embedded-type semiconductor laser, in order to compensate for the influence of residual Si at the regrowth interface surface, doping with Zn takes place, and a layer n-inverted by the residual Si is re-inverted to a p-type so as to improve the lasing characteristics of the laser (FIG. 16).
Patent Publication 1 U.S. Pat. No. 3,158,651.
Patent Document 2 Japanese Patent Publication Laid-open No. Sho. 59-65434.
Patent Document 3 Japanese Patent Publication Laid-open No. Sho. 51-74580.
Patent Publication 4 U.S. Pat. No. 3,339,486.

In non-patent document 1, IEEE Journal Of Selected Topics In Quantum Electronics, Volume 3, Number 3, page 845 to page 853 (IEEE Journal of Selected Topics in Quantum Electronics, Vol. 3, NO. 3, p 845 to p 853).

### DISCLOSURE OF THE INVENTION

However, in the related art, the etching rate is slow compared to the structural elements of the semiconductor crystal and it is easy for contaminants to remain on the surface so that, for example, as published in IEEE Journal of selected Topics in Quantum Electronics, Vol. 3, No. 3, p 845 to p 853, even if an InP surface is etched within a growth chamber using PCl₃ as an etching gas, the Si is substantially not etched and remains on the surface. Further, in the results of evaluation by these inventors, in the vicinity of a normal crystal growth temperature, even if etching is implemented within a crystal growth chamber as shown in U.S. Pat. No. 3,158,651, residual Si of a regrowth interface cannot be eliminated in a straightforward manner. Moreover, if the substrate temperature is raised too high in order to eliminate the residual Si, if the etching is too deep, impurity diffusion and crystal defects occur within the original semiconductor layer, change in shape occurs due to etching, and it becomes no longer possible to make a device structure as the design intends.

Further, in the case of using the technology disclosed in U.S. Pat. No. 3,339,486, by doping surplus Zn to compensate for the influence on an n-type layer forming due to residual Si, demerits are provided such that inter-valence band absorption (IVBA) at a cladding layer is made to increase, and in the case of dispersion at an active layer, internal differential quantum efficiency (ηi) is made to fall.

In order to resolve this situation, it is an object of the present invention to provide a semiconductor surface cleaning procedure that does not induce the occurrence of impurity diffusion and crystal defects within the original semiconductor layers, that keeps changes in shape to a minimum, and that stably and reproducibly eliminates impurity contamination and physical damage at a semiconductor substrate surface prior to crystal growth and a semiconductor surface prior to regrowth, and provide an embedded semiconductor laser structure having superior lasing characteristics where increase of IVBA and reduction of ηi due to doping of surplus Zn etc., and crystal defects do not occur.

The inventors predict the following as the reasons elimination of specific contamination adhered to a semiconductor surface is difficult. In the case where an etching agent is made to act on contaminant adhered to a semiconductor layer surface, a chemical reaction occurs between the etching agent and the specific contaminant. However, even if the bond strength of bonds occurring due to this chemical reaction is relatively weak so that a compound is formed by the contaminant bonding with the etching agent so as to be detached from the semiconductor surface, it is predicted that the contaminant will become reattached to the semiconductor surface directly after breaking of the bonds. It is therefore predicted that elimination will be difficult because of reattachment of specific contaminant adhered to the semiconductor surface to the semiconductor layer.

Based on these predictions, the inventors found that by causing both a source material having an etching action and a crystal growth material to come into contact with a semiconductor layer surface constituting a target of cleaning treatment, is it possible to suppress reattachment and effectively eliminate contaminants through etching.

A semiconductor surface cleaning method of the present invention is therefore a cleaning treatment method for eliminating contaminant adhered to the surface of a semiconductor layer comprised of a cleaning treatment step of simultaneously or alternately causing an etching agent having an etching action with respect to the semiconductor layer and crystal growth source material to come into contact with the semiconductor layer.

Further, a semiconductor surface cleaning method of the present invention is therefore a cleaning treatment method for eliminating contaminant adhered to the surface of a semiconductor layer comprised of a cleaning treatment step of exposing the surface of the semiconductor layer to an atmosphere including an etching agent having an etching action with respect to the semiconductor layer and crystal growth source material.

A semiconductor surface cleaning method of the present invention is therefore a cleaning treatment method for eliminating contaminant adhered to the surface of a semiconductor layer comprised of a cleaning treatment step of simultaneously supplying a first gas including an etching agent having an etching action with respect to the semiconductor layer and a second gas including crystal growth source material to the surface of the semiconductor layer.

When the etching agent acts on the semiconductor layer surface, contaminant attached to the surface of the semiconductor layer is detached from the surface. However, part of the detached contaminant becomes reattached to the surface of the semiconductor layer. It is therefore necessary to sufficiently suppress reattachment of contaminant in order to increase cleanliness of the semiconductor layer. In the present invention, reattachment is suppressed and contaminant is effectively eliminated through etching by causing the etching agent and the crystal growth source material to come into contact with the semiconductor layer surface. The reason why it is possible to prevent reattachment of contaminant using this method is not completely clear but it is predicted that after detachment of the contaminant from the surface of the semiconductor layer, the site formerly occupied up to this time by the contaminant is rapidly taken over by the crystal growth source material.

In the cleaning treatment method of the present invention, a configuration is possible where the first gas and the second gas are supplied intermittently. As a result of this, it is possible to eliminate contamination of the surface of the semiconductor layer in a substantially more effective manner.

In the cleaning treatment method of the present invention, a configuration is possible where a difference in layer thickness of the semiconductor layer before and after implementation of the cleaning treatment step is 100 nm or less. As a result, it is possible to realize a sufficiently high degree of cleanliness.

In the cleaning treatment method of the present invention, a configuration is possible where layer thickness of the semiconductor layer is not substantially reduced during implementation of the cleaning treatment step. Here, “not substantially reduced” means that the layer thickness of the semiconductor layer does not change at all or only reduces slightly at a rate of change of layer thickness of 0.1 nm/sec or less. By making the configuration such that the layer thickness of the semiconductor layer does not substantially reduce, it is possible to implement a sufficiently high degree of cleanliness with regards to the semiconductor layer surface.

In the above, it is possible to implement a sufficiently high degree of cleanliness by controlling the change of layer thickness of the semiconductor layer constituting the target of cleaning treatment. The reason why is not completely clear but it is predicted that after detachment of the contaminant from the surface of the semiconductor layer, the site formerly occupied up to this time by the contaminant is reliably taken over by the crystal growth source material. Control of the change of layer thickness of the semiconductor layer can be achieved, for example, by adjusting the quantitative ratio of the etching agent and the crystal growth source material. For example, by adjusting the quantitative ratio of the etching gas and source material gas appropriately when providing the gases to the surface of the semiconductor, the semiconductor layer constituting a target of cleaning treatment is substantially not etched, and a new semiconductor layer is substantially not grown at the upper part of the semiconductor layer.

There are also cases where the balance between the etching agent and the crystal growth source material is lost so that there is an inclination towards the etching side, reattachment of etched matter occurs, and sufficient cleanliness is not achieved. On the other hand, in the event of inclination towards film-forming, a new semiconductor layer is formed without the contaminant being sufficiently eliminated and sufficient cleaning cannot be achieved.

In the cleaning treatment method of the present invention, a configuration is possible where, when it is taken that: a symbol for rate of change of layer thickness of the semiconductor layer is positive when layer thickness increases and is negative when layer thickness decreases, rate of change of layer thickness of the semiconductor layer during implementation of the cleaning treatment step is R, rate of change of layer thickness of the semiconductor layer in the case of supplying only the first gas to the semiconductor layer surface is r1, and rate of change of layer thickness of the semiconductor layer in the case of supplying only the second gas to the semiconductor layer surface is r2, the amount of the first gas and the second gas supplied is adjusted in such a manner that an absolute value for the rate of change of layer thickness becomes:
|R|<|r₂|<|r₁|

As a result, the balance of supplying the etching agent and the crystal growth source material is appropriate, contaminant adhered to the semiconductor layer surface can be effectively eliminated, and reattachment of detached contaminant to the semiconductor layer can be suppressed.

In the cleaning treatment method of the present invention a configuration is possible where R<0. As a result, it is possible to realize a sufficiently high degree of cleanliness regarding the semiconductor layer surface.

In the cleaning treatment method of the present invention a configuration is possible where |R| is 0.1 nm/sec or less. As a result, the balance of supplying the etching agent and the crystal growth source material is appropriate, contaminant adhered to the semiconductor layer surface can be effectively eliminated, and reattachment of detached contaminant to the semiconductor layer can be suppressed. Further, design of device structure is straightforward.

The cleaning treatment method of the present invention is such that the crystal growth source material can be configured to include metal organic. The cleaning treatment method of the present invention can also be configured so that the etching agent is a halogen element or compound thereof.

The cleaning treatment method of the present invention can also be configured in such a manner that the semiconductor layer is comprised of compound semiconductor. The cleaning treatment method of the present invention can also be configured in such a manner that the semiconductor layer is comprised of a group III-V compound semiconductor.

In the event that the crystal growth source material is a compound including a group III element constituting the semiconductor layer, the positions of vacant lattices within the semiconductor layer formed by the etching agent can be made to be taken up by configuration elements of the semiconductor layer, and the forming of transition layers etc. at the surface can be prevented.

It is also possible for the group III element constituting the semiconductor layer to be comprised of a single species. In this way, it is possible to suppress the occurrence of forming of transition layers and compositional changes from occurring during cleaning treatment of the surface of the semiconductor layer.

The cleaning treatment method of the present invention can also be configured in such a manner that the group III element constituting the semiconductor layer is indium (In). In InP vapor phase epitaxy, a growth temperature of 600 to 650 degree centigrade is usually adopted. This is to prevent diffusion of an impurity such as, for example, zinc etc. added with the intention of preventing phosphorus that is a group V element from becoming detached and to provide conductivity to the crystal so as to obtain an impurity profile as the design intended. However, in the event of adopting this comparatively low temperature growth temperature, the cleaning treatment of the growth interface becomes substantially more difficult. Typically, cleaning treatment of the growth interface using etching gas is such that elimination efficiency improves for a higher temperature atmosphere. However, with InP family semiconductors, an upper limit exists for the cleaning treatment temperature, it is difficult to prevent contamination of the growth interface, an in particular, there is a problem that silicon contamination is acute. According to the present invention, it is possible to effectively resolve problems with contamination of growth boundaries.

Further, according to the present invention, a method of manufacturing a semiconductor shown in the following is provided. Here, “semiconductor device”, may include optical devices such as light-emitting devices, light-receiving devices, and light modulators, and electronic devices such as field effect transistors and bipolar transistors, etc.

A method of manufacturing a semiconductor device of the present invention comprises the steps of forming a first semiconductor layer at an upper part of a semiconductor substrate, subjecting the surface of the first semiconductor layer to cleaning treatment, and forming a second semiconductor layer on the first semiconductor layer. The step of subjecting the surface of the first semiconductor layer to cleaning treatment includes a step of causing an etching agent having an etching action with respect to the semiconductor layer and crystal growth source material to come into contact with the surface of the semiconductor layer.

Further, a method of manufacturing a semiconductor device of the present invention comprises the steps of forming a first semiconductor layer at an upper part of a semiconductor substrate, subjecting the surface of the first semiconductor layer to cleaning treatment, and forming a second semiconductor layer on the first semiconductor layer. The step of subjecting the surface of the first semiconductor layer to cleaning treatment includes a step of exposing the surface of the semiconductor layer to an atmosphere including an etching agent having an etching action with respect to the semiconductor layer and crystal growth source material.

Moreover, a method of manufacturing a semiconductor device of the present invention comprises the steps of forming a first semiconductor layer at an upper part of a semiconductor substrate, subjecting the surface of the first semiconductor layer to cleaning treatment, and forming a second semiconductor layer on the first semiconductor layer. The step of subjecting the surface of the first semiconductor layer to cleaning treatment includes a step of simultaneously providing a first gas including an etching agent having an etching action with respect to the semiconductor layer and a second gas including crystal growth source material to the surface of the semiconductor layer.

When the etching agent acts on the semiconductor layer surface, contaminant attached to the surface of the semiconductor layer is detached from the surface. However, part of the detached contaminant becomes reattached to the surface of the semiconductor layer. It is therefore necessary to sufficiently suppress reattachment of contaminant in order to increase cleanliness of the semiconductor layer. In the present invention, reattachment is suppressed and contaminant is effectively eliminated through etching by causing the etching agent and the crystal growth source material to come into contact with the semiconductor layer surface. The reason why it is possible to prevent reattachment of contaminant using this method is not completely clear but it is predicted that after detachment of the contaminant from the surface of the semiconductor layer, the site formerly occupied up to this time by the contaminant is rapidly taken over by the crystal growth source material.

In the method of manufacturing a semiconductor device of the present invention, a configuration is possible where the first gas and the second gas are supplied intermittently. As a result of this, it is possible to eliminate contamination of the surface of the semiconductor layer in a substantially more effective manner.

In the method of manufacturing a semiconductor device of the present invention, a configuration is possible where a difference in layer thickness of the second semiconductor layer before and after implementation of the step of subjecting the surface of the first semiconductor layer to cleaning treatment is 100 nm or less. As a result, it is possible to realize a sufficiently high degree of cleanliness.

In the method of manufacturing a semiconductor device of the present invention, a configuration is possible where layer thickness of the second semiconductor layer is not substantially reduced during implementation of the step of subjecting the surface of the first semiconductor layer to cleaning treatment. Here, “not substantially reduced” means that the layer thickness of the first semiconductor layer does not change at all or only reduces slightly at a rate of change of layer thickness of 0.1 nm/sec or less. By making the configuration such that the layer thickness of the first semiconductor layer does not substantially reduce, it is possible to implement a sufficiently high degree of cleanliness with regards to the semiconductor layer surface.

In the above, it is possible to implement a sufficiently high degree of cleanliness by controlling the change of layer thickness of the first semiconductor layer constituting the target of cleaning treatment. The reason why is not completely clear but it is predicted that after detachment of the contaminant from the surface of the semiconductor layer, the site formerly occupied up to this time by the contaminant is reliably taken over by the crystal growth source material.

Control of the change of layer thickness of the first semiconductor layer can be achieved, for example, by adjusting the quantitative ratio of the etching agent and the crystal growth source material. For example, by adjusting the quantitative ratio of the etching gas and source material gas appropriately when providing the gases to the surface of the semiconductor, the semiconductor layer constituting a target of cleaning treatment is substantially not etched, and a new semiconductor layer is substantially not grown at the upper part of the semiconductor layer.

There are also cases where the balance between the etching agent and the crystal growth source material is lost so that there is an inclination towards the etching side, reattachment of etched matter occurs, and sufficient cleanliness is not achieved. On the other hand, in the event of inclination towards film-forming, a new semiconductor layer is formed without the contaminant being sufficiently eliminated and sufficient cleaning cannot be achieved.

In the method of manufacturing a semiconductor device of the present invention, when it is taken that a symbol for rate of change of layer thickness of the first semiconductor layer is positive when layer thickness increases and is negative when layer thickness decreases, rate of change of layer thickness of the first semiconductor layer during implementation of the step of subjecting the surface of the first semiconductor layer to cleaning treatment is R, rate of change of layer thickness of the first semiconductor layer in the case of supplying only the first gas to the first semiconductor layer surface is r₁, and rate of change of layer thickness of the first semiconductor layer in the case of supplying only the second gas to the first semiconductor layer surface is r₂, the amount of the first gas and the second gas supplied is adjusted in such a manner that an absolute value for the rate of change of layer thickness becomes:
|R|<|r₂|<|r₁|

As a result, the balance of supplying the etching agent and the crystal growth source material is appropriate, contaminant adhered to the semiconductor layer surface can be effectively eliminated, and reattachment of detached contaminant to the semiconductor layer can be suppressed.

In the method of manufacturing a semiconductor device of the present invention a configuration is possible where R<0. As a result, it is possible to realize a sufficiently high degree of cleanliness regarding the semiconductor layer surface.

In the method of manufacturing a semiconductor device of the present invention a configuration is possible where |R| is 0.1 nm/sec or less. As a result, the balance of supplying the etching agent and the crystal growth source material is appropriate, contaminant adhered to the semiconductor layer surface can be effectively eliminated, and reattachment of detached contaminant to the semiconductor layer can be suppressed.

The method of manufacturing a semiconductor device of the present invention is such that the crystal growth source material can be configured to include metal organic.

The method of manufacturing a semiconductor device of the present invention can also be configured so that the etching agent is a halogen element or compound thereof.

The method of manufacturing a semiconductor device of the present invention can also be configured so that the first semiconductor layer is comprised of compound semiconductor.

The method of manufacturing a semiconductor device of the present invention can also be configured so that the first semiconductor layer is comprised of group III-V compound semiconductor. At this time, a configuration is possible where it is possible for the crystal growth source material to be a compound including a group III element constituting the first semiconductor layer. It is also possible for the group III element constituting the first semiconductor layer to be comprised of a single species. In this way, it is possible to suppress the occurrence of forming of transition layers and compositional changes from occurring during cleaning treatment of the surface of the semiconductor layer.

The method of manufacturing a semiconductor device of the present invention can also be configured so that the group III element constituting the first semiconductor layer is indium (In). In InP vapor phase epitaxy, a growth temperature of 600 to 650 degree centigrade is usually adopted. This is to prevent phosphorus that is a group V element from becoming detached and to prevent diffusion of an impurity of zinc so as to obtain an impurity profile as the design intended. However, in the event of adopting this comparatively low temperature growth temperature, the cleaning treatment of the growth interface becomes substantially more difficult. Typically, cleaning treatment of the growth interface using etching gas is such that elimination efficiency improves for a higher temperature atmosphere. However, with InP family semiconductors, an upper limit exists for the cleaning treatment temperature, it is difficult to prevent contamination of the growth interface, an in particular, there is a problem that silicon contamination is acute. According to the present invention, it is possible to effectively resolve problems with contamination of growth boundaries. The method of manufacturing a semiconductor device of the present invention can also be configured so that the first semiconductor layer and the second semiconductor layer are formed using vapor phase epitaxy.

In the method of manufacturing a semiconductor device of the present invention, a configuration is also possible where a mask is formed on the first semiconductor layer after the step of forming the first semiconductor layer, and after eliminating the mask, the step of subjecting the surface of the first semiconductor layer to cleaning treatment is implemented. In the event that this process is undertaken, the surface of the first semiconductor layer is a regrowth surface, and it is therefore easy for a large number of impurities to become attached to the surface due to contamination by the atmosphere and remaining mask material, etc. According to the present invention, it is possible to effectively eliminate these kinds of impurities.

A semiconductor device of the present invention therefore has a concentration of residual Si of a regrowth interface within a p-type semiconductor layer having a surface density of 5×10¹¹ atoms/cm².

Further, a semiconductor integrated device of the present invention therefore has a concentration of residual Si of a regrowth interface within a p-type semiconductor layer having a surface density of 5×10¹¹ atoms/cm².

As a result of this, a structure where there are few crystal defects and little dopant diffusion is possible without increases in IVBA or decreases in ηi, leakage currents that cause breakdown voltage of the block layer to fall can be suppressed, and as a result, superior lasing characteristics can be obtained. Further, the effect where leakage current between devices can be suppressed due to the device structure is obtained.

The regrowth boundaries may be, for example:
(i) an interface of a p-type current block layer and a layer connected to a lower section of the p-type current block layer,
(ii) an interface of a p-type cladding layer and a layer connected to a lower section of the p-type current block layer,
(iii) A regrowth interface within a p-type cladding layer.

An example of (i) may be an interface between a p-type current block layer and a p-type substrate. An example of (ii) may be a p-type cladding layer and an active layer or optical guide layer etc. at a lower part of the p-type cladding layer.

The concentration of the residual Si of the regrowth interface is such that surface concentration is 5×10¹¹ atoms/cm² or less, and preferably 1×10¹¹ atoms/cm² or less. As a result of this, it is possible to improve breakdown characteristics and reduce current leakage.

The semiconductor device and the semiconductor integrated device of the present invention may also have an active MMI structure.

As shown in the above, the present invention has the following effects.

In a first effect, according to the cleaning treatment method of the present invention, inducing of the occurrence of impurity diffusion and crystal defects within the original semiconductor layer does not occur, changes in shape are kept to a minimum, and stable and reproducible elimination of impurity contamination and physical damage at a semiconductor substrate surface prior to crystal growth and a semiconductor surface prior to regrowth is possible. This contributes greatly to the improvement of performance of a semiconductor device having a growth interface.

In a second effect, residual Si concentration of a regrowth interface between a first embedded layer constituting a current block layer of an embedded optical semiconductor device and a second embedded layer constituting a cladding layer is taken to be 5×10¹¹ atoms/cm² or less. It is therefore possible to suppress leakage current causing the breakdown voltage of the block layer to fall, and it is possible to provide an embedded semiconductor laser having superior lasing characteristics.

In a third effect, residual Si concentration of a regrowth interface between a first embedded layer constituting a current block layer of an embedded optical semiconductor device and a second embedded layer constituting a cladding layer is taken to be 5×10¹¹ atoms/cm² or less. It is therefore no longer necessary to carry out high-concentration doping of Zn in order to re-invert a layer made into an n-type by residual Si into a p-type, increase of IVBA and decrease of ηi can be avoided, and it is possible to provide an embedded semiconductor laser having superior lasing characteristics.

In a fourth effect, at the optical semiconductor device, concentration of residual Si of the regrowth interface within the cladding layer is 5×10¹¹ atoms/cm² or less. Leakage current between devices can therefore be suppressed, and it is possible to provide an integrated device in the possession of an embedded semiconductor laser having superior operating characteristics.

### BRIEF DESCRIPTION OF THE DRAWINGS

FIG. 1 is a view showing a structure for a semiconductor layer made using an embodiment.

FIG. 2 is a view showing SIMS measurement results for residual impurity concentration in the embodiment.

FIG. 3 is a further view showing SIMS measurement results for residual impurity concentration in the embodiment.

FIG. 4 is another view showing SIMS measurement results for residual impurity concentration in the embodiment.

FIG. 5 is a view showing SIMS measurement results for residual impurity concentration in the embodiment.

FIG. 6 is another view showing SIMS measurement results for residual impurity concentration in the embodiment.

FIG. 7 is a further view showing SIMS measurement results for residual impurity concentration in the embodiment.

FIG. 8 is a view showing residual impurity concentrations measured by SIMS as a function of TMIn flow rate in the embodiment.

FIG. 9 is another view showing residual impurity concentrations measured by SIMS as a function of TMIn flow rate in the embodiment.

FIG. 10 is a view showing an embedded-type semiconductor laser structure of a second embodiment.

FIG. 11 is a view showing a structure for an optical semiconductor device of the present invention in a fifth embodiment.

FIG. 12 is a view showing a structure for an optical semiconductor device of the present invention in a sixth embodiment.

FIG. 13 is a view showing dependence on residual Si concentration of a second regrowth interface for threshold current in the fifth embodiment.

FIG. 14 is a view showing dependence on residual Si concentration of a second regrowth interface for slope efficiency in the fifth embodiment.

FIG. 15 is a view showing dependence on residual Si concentration of a second regrowth interface for light output under 150 mA current injection in the fifth embodiment.

FIG. 16 is a cross-sectional view of a conventional embedded-type semiconductor laser.

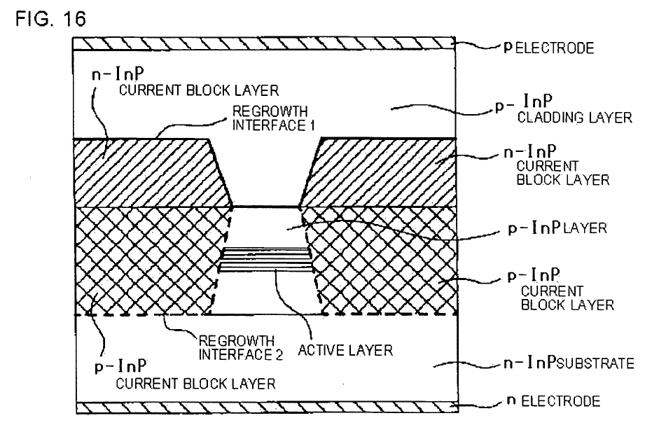

### BEST MODE FOR CARRYING OUT THE INVENTION

The semiconductor layer constituting a target of cleaning treatment in the present invention may be a group III-V compound semiconductor of an InP family such as InGaAs, InGaAsP, AlGaInAs, or InAsP etc., a GaAs family such as AlGaAs, InGaP, AlGaInP, GaAsSb, InGaAsN etc., or a GaN, AlGaN, GaInN, AlGaInN, BAlGaInN, etc., a group II-VI compound semiconductor such as ZnSe, ZnTe, MgZnSe,MgZnCdSe, MgZnSeTe, ZnSeTe, ZnO, MgZnO, MgCdZnO, or in addition may be a semiconductor such as silicon and a compound thereof, or germanium and a compound thereof, etc.

The semiconductor layer constituting a target of cleaning treatment of the present invention may be composed of three element groups or four or more element groups. Of these, much improved results are obtained for the case of applying the present invention to elimination of contamination adhered to the surface of a group III-V compound semiconductor layer as a result of device manufacturing processes or exposure to the atmosphere. In particular, application to the elimination of silicon where sufficient removal was difficult in the related art is particularly effective.

An example can be shown of a halogen element or compound thereof that bonds with a large number of elements to form volatile compounds as an etching agent of the present invention. Of these, use of a source material including Chlorine (Cl) is preferable from the point of view that handling is straightforward.

Here, t-butyl chloride ((CH₃)₃CCI: TBCl), bis(dimethylamino) phosphine chloride ([N (CH₃)₂]₂PCI:BDMAPCl), hydrogen chloride (HCl), and chloromethane (CH₃Cl), carbon tetrachloride (CCl₄), bis(dimethylamino) arsino-chloride ([N (CH₃)₂]₂AsCl), phosphorous trichloride (PCl₃), arsenic trichloride AsCl₃, chlorine (Cl₂), or similarly Br family source material, I family source material, or F family source material may be shown as examples of etching agents of the present invention. Of these, when t-butyl chloride is used, it is possible to maintain stoichometry of the semiconductor layer constituting the target of the cleaning treatment comparatively easily and effective etching can be carried out. For example, in the event that the semiconductor layer is a group III-V semiconductor, when the etching gas includes a specific group V element, when the semiconductor layer constituting the target of cleaning treatment includes a group V element of a different species than that contained in the etching gas, a problem occurs where a degeneration layer is formed at the surface during the cleaning treatment. The t-butyl chloride can be preferably used because it does not contain a group V element and does not cause a degeneration layer during the cleaning treatment. Further, in the event of using bis(dimethylamino) phosphine chloride, it is possible to keep temperature dependence of the etching performance comparatively suppressed so as to enable stable cleaning treatment to be carried out.

Moreover, in the event that there is one species of group III elements constituting the semiconductor layer that is the target of cleaning treatment, it is desirable that it is difficult for forming of transition layers and compositional changes to occur during surface treatment of the present invention, and in the event that the group III element constituting the first semiconductor is indium (In), for example, InP, InAs, InN, InSb etc., or gallium (Ga), for example, GaAs, GaP, GaN, GaSb, etc., more marked results appear.

In the event that the present invention is implemented using a vapor phase epitaxy device to grow a semiconductor layer, marked effects are obtained, with even more marked effects appearing in the case of Metal Organic Vapor Phase Epitaxy (MOCVD) using an organic metal in the growth material. Further, in this case, there is no specific limitation for hydrides and metal organic gas taken as crystal growth source material, and any type of hydrides and any type of metal organic gases necessary for obtaining the desired compound semiconductor may be used.

Next, a detailed description is given with reference to the drawings of embodiments of the present invention.

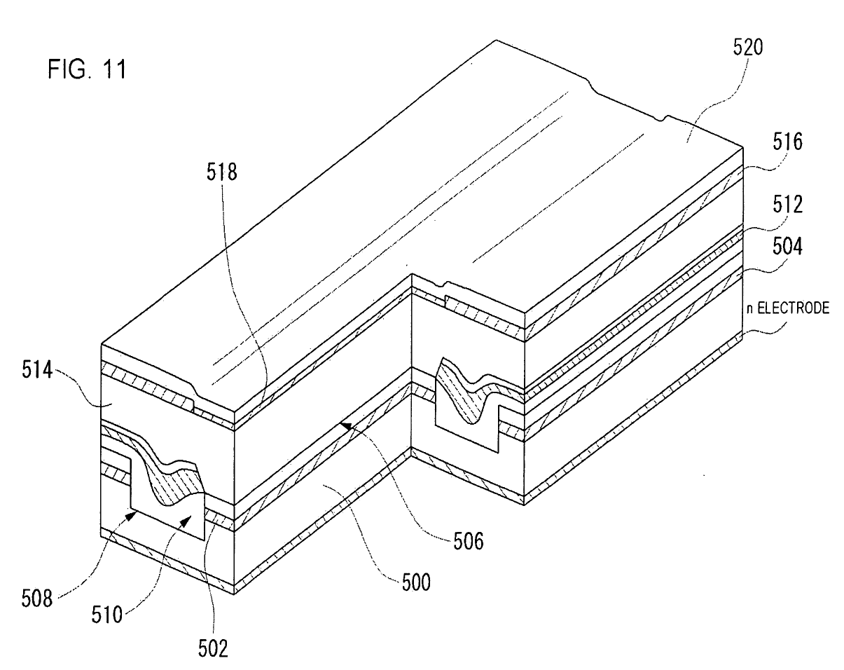

Referring to FIG. 11, a structural view of an optical semiconductor device is shown as a first embodiment of the present invention. This optical semiconductor device is a semiconductor laser having a Double Channel Planar Buried Hetero Structure (DC-PBH) that is completed by forming a crystal growth process three times. Namely, first, a wave guide layer composed of a double hetero structure including an active layer 502 on an n-type InP substrate 500 is grown and the wave guide layer is subjected to desired patterning via photolithographic processes employing dielectric masks etc. and then a wave guide having a recombination layer 504 with spaced channels on either side is formed by dry etching or wet chemical-etching and the like.

Next, a second crystal growth process is implemented with just a dielectric film remaining on the wave guide, so that the wave guide is buried by a p-InP block layer 510 and an n-InP block layer 512. A regrowth interface (boundary) at this time is referred to as a first regrowth interface 508. Next, dielectric film on a mesa including an active layer 502 is removed, and a third crystal growth process is implemented. Here, directly before starting growth of a p-InP cladding layer 510, at the crystal growth apparatus, gas having an etching action and growth source gas are supplied at exactly the same etching rate and growth rate so that the surface of this semiconductor is cleaned. At this time, when rate of change of film thickness while subjecting the surface to cleaning treatment is measured using an optical-type film thickness monitor etc., the film thickness reduces slightly but only by a magnitude of 0.1 nm/sec or less. After cleaning treatment, a p-InP cladding layer 514 and a p-type contact layer 518 are grown. An interface at the time of carrying out this regrowth process for the second time is referred to as a second regrowth interface. After this, the optical semiconductor device of the present invention is completed via a normal electrode forming process.

With this optical semiconductor device, concentration of residual Si at the second regrowth interface has a low surface density of 5×10¹⁰ atoms/cm². The amount of current leaking from directly above the active layer to the current block layer is therefore extremely small. Further, doping of the vicinity of the second regrowth interface with p-type dopant for surplus Zn etc. in order to cancel out the effect of residual Si is not necessary, and increases in internal loss and drops in internal differential quantum efficiency do not occur. Therefore, in the event, for example, that this optical semiconductor device is a semiconductor laser, it is possible to obtain a semiconductor laser with a low threshold value, high efficiency, and high output. Further, in the event that the optical semiconductor device is an optical semiconductor amplifier, a semiconductor amplifier of high gain and high saturation output can be obtained.

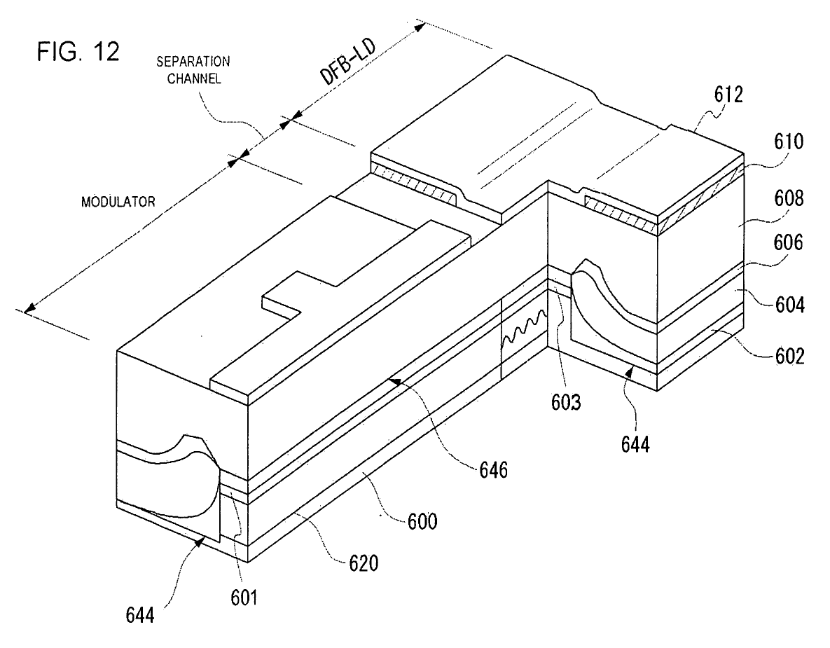

FIG. 12 is a structural view of an optical semiconductor integrate element of a second embodiment. This optical semiconductor integrated device is a modulator integrated type DFB-LD completed via the fourth crystal growth process. Namely, a double-hetero (DH) structure containing an active layer for a laser is grown on an n-type InP substrate 600 formed with diffraction gratings only at portions constituting a semiconductor laser. A mask is then formed on the semiconductor laser portions using photolithographic processes employing a dielectric mask etc., and a modulator portion is etched using dry etching or wet chemical etching.

Next, a DH structure containing an active layer 601 for modulator use is grown in the second crystal growth. Next, a mask is formed at a wave guide section and a modulator wave guide section for the semiconductor laser by a photolithographic process employing a dielectric mask and the like again. and portions other than the wave guide are then etched by dry etching or wet chemical etching. Next, dielectric film remains only on the wave guide for semiconductor laser use and modulator use, a third crystal growth process is implemented, and a p-InP block layer 602, Semi-Insulating (SI) -InP block layer 604, and an n-InP block layer 606 are grown. A regrowth interface at this time is referred to as a second regrowth interface 644.

Next, dielectric film on the wave guide for semiconductor laser use and modulator use is removed, and a fourth crystal growth process is implemented. Here, directly before starting growth of a p-InP cladding layer 608, at the crystal growth apparatus, gas having an etching action and growth source gas are supplied at exactly the same etching rate and growth rate so that the surface of this semiconductor is cleaned. At this time, when rate of change of film thickness while subjecting the surface to cleaning treatment is measured using an optical-type film thickness monitor etc., the film thickness reduces slightly but only by a magnitude of 0.1 nm/sec or less. After cleaning treatment, the p-InP cladding layer 608 and a p-type contact layer 612 are grown. An interface at the time of carrying out this crystal growth process for the fourth time is referred to as a third regrowth interface 646. After this, the optical semiconductor device of the present invention is completed via a normal electrode forming process.

With this semiconductor device, the concentration of residual Si for the third regrowth interface is low at a surface concentration of 5×10¹⁰ atoms/cm². In addition to the current leaking from directly above the semiconductor laser and modulator to the current block layer being extremely small, the current leaking between the semiconductor laser and the modulator is also extremely small. Further, doping of the vicinity of the second regrowth interface with p-type dopant for surplus Zn etc. in order to cancel out the effect of residual Si is not necessary. There is also no increase in internal loss or reduction in internal differential quantum efficiency accompanying diffusion of p-type dopant at this semiconductor laser portion, and no uneven distribution of electric field strength accompanying diffusion of p-type dopant. A low threshold value, high-efficiency, high output, high-speed modulator integrated-type DFB-LD semiconductor laser can therefore be obtained.

With the optical semiconductor device of this embodiment, by applying cleaning treatment techniques of the present invention to the first regrowth interface to reduce residual Si concentration, leakage current is reduced and device characteristics are improved.

With this optical semiconductor integrated device, by applying the cleaning treatment techniques of the present invention to the first regrowth interface and the second regrowth interface to reduce residual Si concentration, leakage current between the each device section and for the single device section is reduced and device characteristics are improved.

In order to clarify the description of the present invention and other objects, features and advantages, a description is given in the following of the embodiments of the present invention with reference to the drawings, but the present invention is by no means limited to that disclosed in the embodiments.

First Embodiment

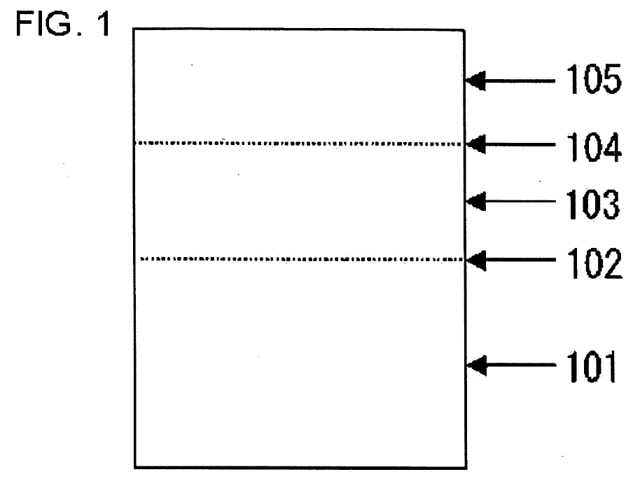

This embodiment described a residual impurity removal for a growth interface in the case of re-growing InP on InP using MOVPE techniques. Here, t-butyl chloride (TBCl: (CH₃)₃CCl) is used as the source material having an etching action, and trimethylindium (TMIn) and phosphine (PH₃) are used as the crystal growth source material. As shown in FIG. 1, after an undoped InP layer 103 is grown to 1.0 μm as a growth layer for the first time using MOVPE techniques under a low pressure (60 Torr) on the Sn doped {001} InP substrate 101, the wafer is temporarily removed from an MOVPE reactor and is exposed to the atmosphere for twelve hours. Wet chemical treatment etc. is not implemented. After this, the wafer is again moved back into the MOVPE reactor, and an undoped InP layer 105 is regrown to 0.5 μm as the second growth layer.

At the second growth interface 104 directly before the start of the second growth, in the MOVPE reactor, TBCl, TMIn and PH₃ are supplied to the surface of the wafer for ten minutes to carry out a surface cleaning treatment (sample A). The amount of TBCl supplied during this surface cleaning process is 19.4 μmol/min, which corresponds to an etching rate of 20.5 nm/min, the TMIn is supplied at 15.08 μmol/min, and the PH₃ is supplied at 2.68 mmol/min, with these corresponding to an InP growth rate of 20.5 nm/min. The etching rate for the InP due to TBCl and the InP growth etching rate due to the TMIn and PH₃ are therefore equal and there is no change in layer thickness of the undoped InP layer 103 grown at the first time during the surface cleaning treatment. Further, substrate temperature at the time of the surface cleaning treatment is taken to be 625 degrees centigrade.

For the purposes of comparison, a sample (sample B) for which growth of the undoped InP layer 105 of the second time was started without carrying out the surface cleaning treatment using the TBCl, TMIn and PH₃ at the second growth interface 104 directly before the start of the InP layer growth of the second time was also made.

Analysis of the undoped layer 105 in a depth direction while performing sputtering was also carried out using secondary ion mass spectrometry techniques (SIMS) for the residual impurity concentration at the regrowth interface of the second sample for sample A and sample B.

With the sample B where surface cleaning treatment using TBCl, TMIn and PH₃ was not carried out at the second growth interface 104, C, O and Si is detected as residual impurities at the second growth interface 104, at concentrations of respective surface concentrations corresponding to C: 6.4×10¹⁰ atoms/cm², O: 6.9×10¹¹ atoms/cm², Si: 1.2×10¹² atoms/cm². On the other hand, with sample A where surface cleaning treatment is carried out using TBCl (19.4 μmol/min), TMIn (15.08 μmol/min) and PH₃ (2.68 mmol/min) at the second growth interface 104, all of the residual impurities of C, O, Si etc. detected at the second growth interface 104 were less than or equal to the detection limit. The lower limits of detection in this measurement correspond to C: 6×10⁷ atoms/cm², O: 6×10⁸ atoms/cm², Si: 6×10⁷ atoms/cm². Further, Cl introduced as an etching gas was not detected at all. The lower limit for detection of Cl was in the order of 3×10⁷ atoms/cm².

In this embodiment, a description is given of an example of cleaning treatment of the second growth interface 104 but the present invention may also be applied to cleaning treatment of the first growth interface 102.

Second Embodiment

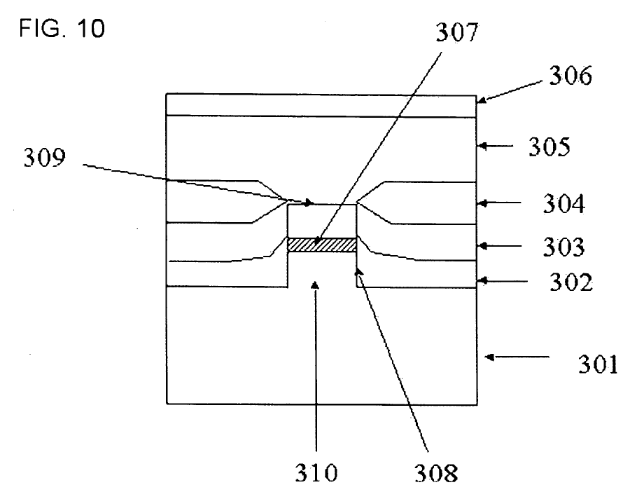

In this embodiment, the present invention is applied to an InP family semiconductor laser device. In this embodiment, after forming multi-layer films of a semiconductor taking an active layer as an uppermost layer, part of the surface of the active layer is covered with a mask, portions on both sides of the mask are removed by etching, and a mesa stripe is provided. At this stage, after implementing cleaning treatment of the present invention, semiconductor layers are buried at both sides of the mesa. After this, the surface of the mesa is subjected to the cleaning treatment of the present invention and a semiconductor layer of an upper layer is formed. The following is a description with reference to FIG. 10.

First, using a normal crystal growth process, a InGaAsP/InGaAsP quantum well 307 constituting an active layer with a double hetero structure is made on an n-type InP substrate 301, and a 2 μm mesa stripe 310 is formed to a depth in the order of 2 μm by dry etching using an SiO₂ mask. After this, this wafer is introduced into an MOVPE reactor, and a first regrowth interface 308 is subjected to surface cleaning treatment of the present invention under the same conditions as for the first embodiment. After this, a current block structure is formed by sequentially forming a p-type InP layer 302, an n-type InP layer 303, and a p-type InP layer 304 one on top of another.

Next, the wafer is extracted from the MOVPE reactor, and the SiO₂ mask is removed using a usual wafer etching process. The wafer is then introduced back into the MOVPE reactor, and the second regrowth interface 309 is once again subjected to surface treatment processing under the same conditions as for the first embodiment. A p-type InP cladding layer 305 and a p-InGaAs contact layer 306 are then formed. After this, a normal electrode forming process and element separation process are carried out so as to complete a buried laser device.

When the voltage—current characteristics and the current—light output characteristics are measured for this device, compared to a conventional device where the surface cleaning treatment of the present invention is not employed, it can be confirmed that the power—light output conversion characteristics at the time of high light output are dramatically improved and the drive voltage necessary to obtain the same light output is substantially reduced. This can be considered to be because of effects where the leakage current is reduced due to the n-type residual impurities such as Si etc. of the first regrowth interface 308 prior to forming of the current block layer by the surface cleaning treatment of the present invention being reduced, current barriers are removed by reducing the n-type residual impurities such as Si etc. of the second regrowth interface 309 prior to forming of the contact layer, and reduction of the drive voltage are achieved.

In this embodiment, both the first regrowth interface 308 and the second regrowth interface 309 are subjected to surface cleaning treatment but it is also possible to subject just one, for example, the second regrowth interface 309, to cleaning treatment.

Third Embodiment

In this embodiment, the semiconductor multi-layer structure is made in the same way as for the first embodiment with the exception that the conditions for cleaning treatment are changed, and the concentration of residual impurities such as C, O and Si at the second growth interface 104 are measured. The conditions for the cleaning treatment are shown in table 1. A description is given in the following of each item in “treatment conditions” of table 1.

(i) Gas Species

Here, t-butyl chloride (TBCl: (CH₃)₃CCl), and bis(dimethylamino) phosphine chloride (BDMAPCl: [N(CH₃)₂]₂PCl) are used.

(ii) Gas Flow Rate

Amount of gas supplied to the MOVPE reactor is shown.

(iii) Etching Rate

The etching rate in the case of only supplying etching gas at the flow rates shown in the table is shown. This value is obtained through pre-testing.

(iv) Growth Rate

The growth rate in the case of only supplying growth gas at the flow rates shown in the table is shown. This value is obtained through pre-testing.

(v) Change in Film Thickness Index

This is defined to be positive when layer thickness increases and negative when layer thickness decreases, and the sum of the growth rate and the etching rate is defined as “change in film thickness index”. This becomes an index for change in film thickness occurring before and after the cleaning treatment process.

(vi) Gas Supply Method.

A continuous method is a method where etching gas and growth gas are supplied continuously for a fixed period of time. An intermittent method is a method where etching gas and growth gas are supplied intermittently for fixed periods of time, with a time of supplying gas and a time of not supplying gas being alternately repeated.

(vii) Wet Chemical Etchting

Prior to cleaning treatment of the undoped InP layer 103, the case of carrying out etching using an etchant is shown by wet etching “present”.

(Samples 1 to 4)

Here, t-butyl chloride (TBCl: (CH₃)₃CCl) or bis(dimethylamino) phosphine chloride (BDMAPCl: [N(CH₃)₂]₂PCl) is used as the source material having an etching action, and trimethylindium (TMIn) and phosphine (PH₃) are used as the crystal growth source material. As shown in FIG. 1, after an undoped InP layer 103 is grown to 1.0 μm as a growth layer for the first time using MOVPE techniques under a low pressure (60 Torr) on the Sn doped {001} InP substrate 101, the wafer is temporarily removed from an MOVPE reactor and is exposed to the atmosphere for twelve hours. After this, the surface of the undoped InP layer 103 is subjected to wet chemical-etching using solution containing sulphuric acid and is rinsed with deionized water.

After this, the wafer is again moved back into the MOVPE reactor, cleaning treatment is carried out under the conditions shown in table 1, and the undoped InP layer 105 is regrown to 0.5 μm as the second growth layer. The cleaning treatment occurring at each sample is as follows.

Cleaning treatment is not carried out at sample 1.

At sample 2, at the second growth interface 104 directly before the start of the second growth, in the MOVPE reactor, TBCl, TMIn and PH₃ are supplied to the surface of the wafer for ten minutes to carry out a surface cleaning treatment. The amount etc. of each gas supplied is as shown in table 1. A continuous method is adopted for supplying the gas. Substrate temperature at the time of the cleaning treatment is taken to be 625 degrees centigrade. The change in film thickness of the undoped InP layer 103 before and after treatment therefore cannot be observed.

At sample 3, at the second growth interface 104 directly before the start of growth for the second time, the following process is carried out within the MOVPE reactor. Namely, a step of (i) after providing TBCl, TMIn and PH₃ to the surface of the wafer for one minute, (ii) a large quantity of PH₃ is supplied for fifteen seconds so as to carry out purging, is repeated twenty times. The amount etc. of each gas supplied is as shown in table 1. Substrate temperature at the time of the cleaning treatment is taken to be 625 degrees centigrade. The change in film thickness of the undoped InP layer 103 before and after treatment was 100 nm or less.

At sample 4, at the second growth interface 104 directly before the start of the second growth, in the MOVPE reactor, bis(dimethylamino) phosphine chloride (BDMAPCl), TMIn and PH₃ are supplied to the surface of the wafer for ten minutes to carry out a surface cleaning treatment. The amount etc. of each gas supplied is as shown in table 1. A continuous method is adopted for supplying the gas. Substrate temperature at the time of the cleaning treatment is taken to be 625 degrees centigrade. The extent of change of layer thickness of the undoped InP layer 103 before and after treatment is as shown in the table.

(Samples 5 and 6)

Here, t-butyl chloride (TBCl: (CH₃)₃CCl) or bis(dimethylamino) phosphine chloride (BDMAPCl: [N(CH₃)₂]₂PCl) is used as the source material having an etching action, and trimethylindium (TMIn) and phosphine (PH₃) are used as the crystal growth source material. As shown in FIG. 1, after an undoped InP layer 103 is grown to 1.0 μm as a growth layer for the first time using MOVPE techniques under a low pressure (60 Torr) on the Sn doped {001} InP substrate 101, the wafer is temporarily removed from an MOVPE reactor and is exposed to the atmosphere for twelve hours. After this, this wafer is again introduced to within the MOVPE reactor without carrying out wet chemical etching, and cleaning treatment is carried out under the conditions shown in table 1. After this, an undoped InP layer 105 of 0.5 μm is regrown as the second growth layer.

The cleaning treatment occurring at each sample is as follows.

Cleaning treatment is not carried out at sample 5. At sample 6, at the second growth interface 104 directly before the start of the second growth, in the MOVPE reactor, TBCl, TMIn and PH₃ are supplied to the surface of the wafer for ten minutes to carry out a surface cleaning treatment. The amount etc. of each gas supplied is as shown in table 1. A continuous method is adopted for supplying the gas. Substrate temperature at the time of the cleaning treatment is taken to be 625 degrees centigrade. The change in film thickness of the undoped InP layer 103 before and after treatment therefore cannot be observed.

The change in layer thickness during cleaning treatment of each sample is 100 nm or less in either case.

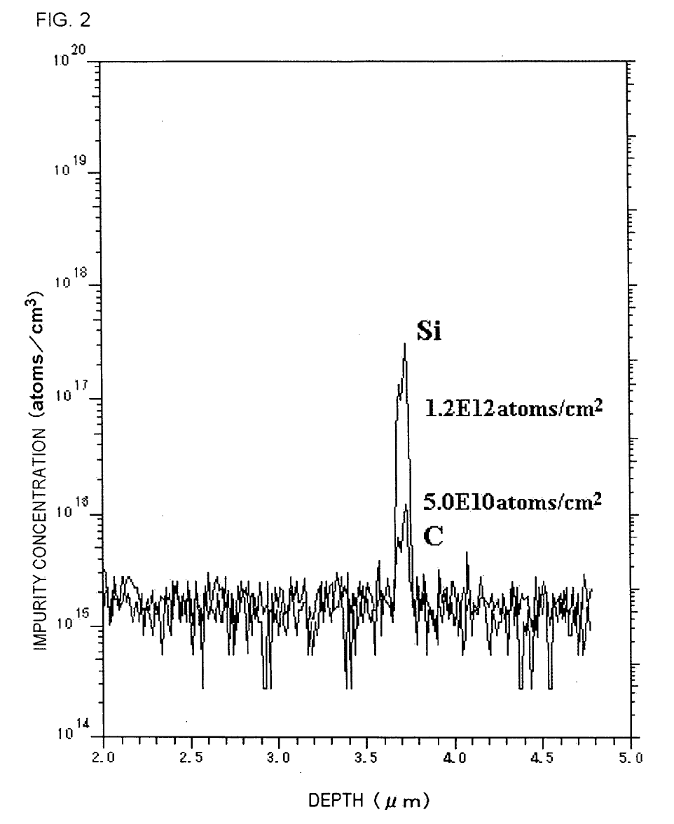

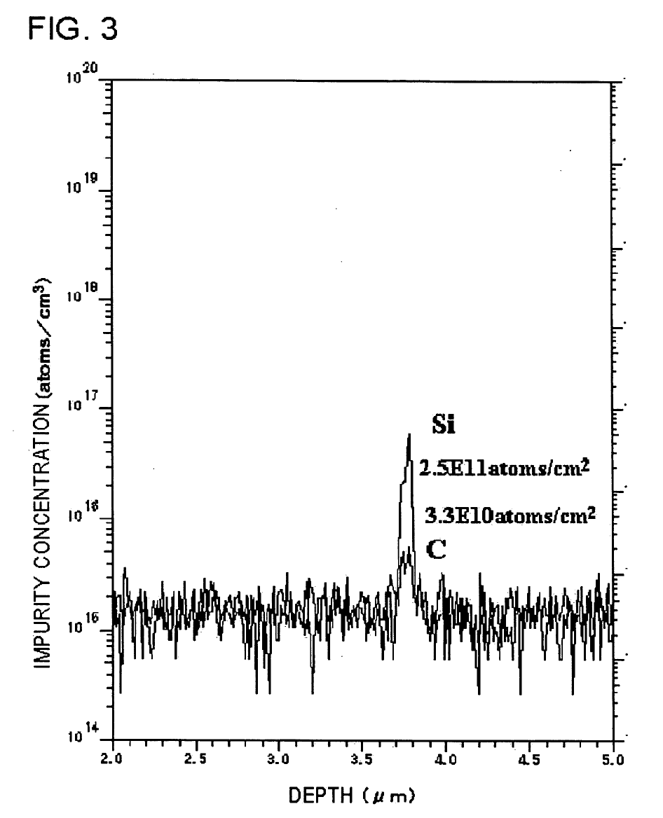

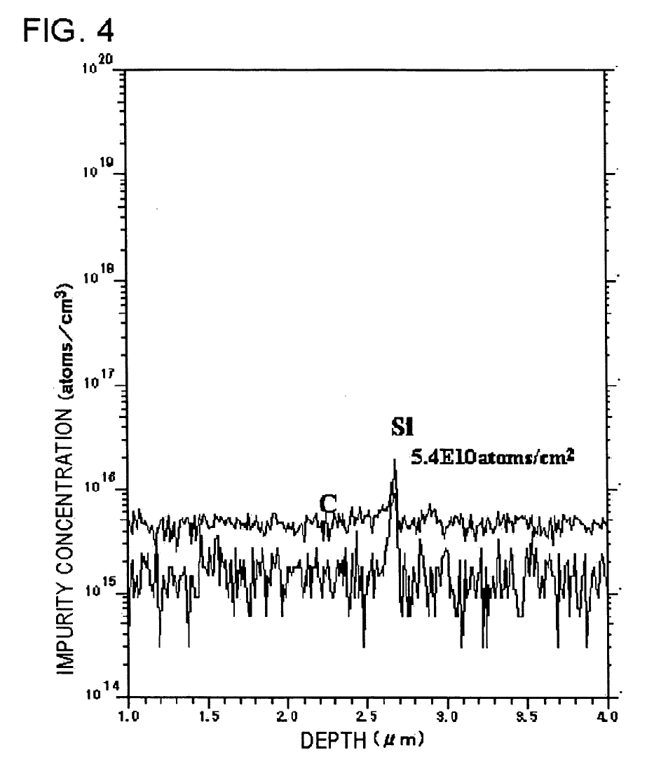

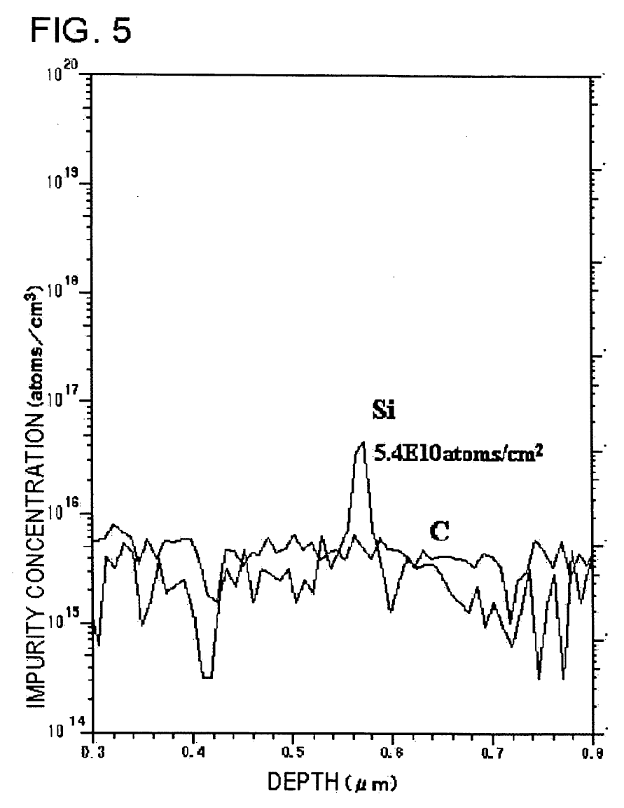

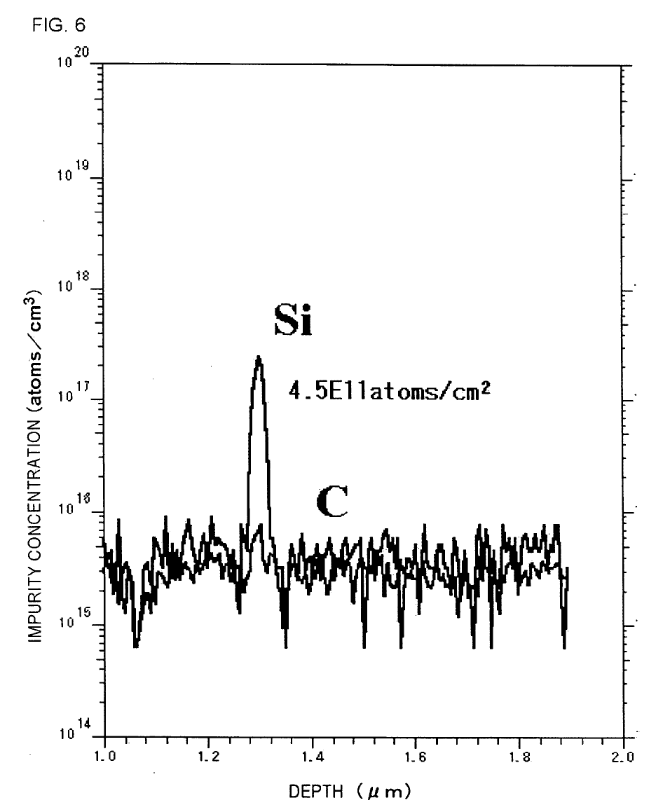

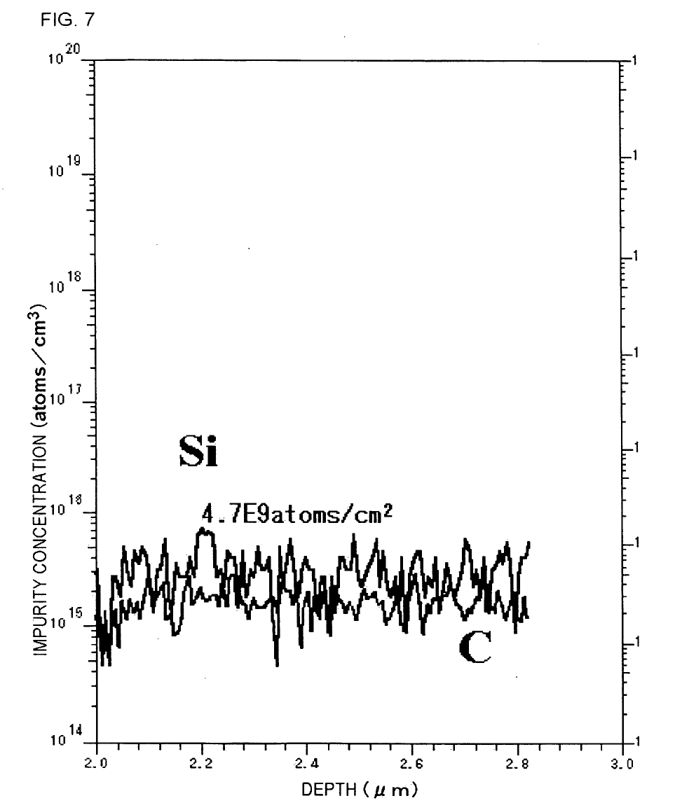

Residual impurity concentration is then measured using SIMS for each of the above samples in the same way as for the first embodiment. The results are shown in table 1 and FIG. 2 to FIG. 7. FIG. 2 to FIG. 7 correspond to the measurement results for samples 1 to 6. In table 1, “n. d.” means that detection was not possible. With sample NO. 5, a numerical value is shown as a reference value because calculation of concentration corresponding to peaks was made difficult due to it being difficult to discriminate this from noise. In FIG. 2 to FIG. 7, the numerical values (vertical axis) calculated as impurity concentration (units: atoms/cm²) are converted as surface density, and these values are described in the drawings so as to correspond to the peaks (units: atoms/cm²).

The following is clear from the results obtained. Namely, the surface density of residual impurities can be substantially reduced by adjusting the ratio of supplying etching gas and growth gas in such a manner that the change in film thickness index becomes 6 nm or less (0.1 nm/sec or less). In particular, Si is effectively eliminated. Further, intermittent is effective as the gas supply method. The density of residual impurities can be markedly reduced by intermittent supplying. The residual impurity concentration without applying the wet chemical etching prior to cleaning treatment is smaller than that with applying the wet chemical etching.

TABLE 1

| SAMPLE | | | 1 | 2 | 3 | 4 | 5 | 6 |
|---|---|---|---|---|---|---|---|---|
| TREATMENT | ETCHING GAS | SPECIES | NONE | TBCL | TBCL | BDMAPCL | NONE | TBCL |
| CONDITIONS | | FLOW RATE | | 19 | 36 | 27 | | 19 |
| | | (μmol/min) | | | | | | |
| | | ETCHING RATE | | 20.5 | 38.8 | 14.4 | | 20.5 |
| | | (nm/min) | | | | | | |
| | GROWTH GAS | SPECIES | | TMIn | TMIn | TMIn | | TMIn |
| | | FLOW RATE | | 16 | 27 | 14 | | 16 |
| | | (μmol/min) | | | | | | |
| | | GROWTH SPEED | | 20.5 | 34.6 | 17.9 | | 20.5 |
| | | (nm/min) | | | | | | |
| | CHANGE IN FILM THICKNESS INDEX (nm/min) | | | 0 | −4.2 | 3.5 | | 0 |
| | GAS SUPPLY SYSTEM | | | CONTIN- | INTER- | CONTIN- | | CONTIN- |
| | | | | UOUS | MITTENT | UOUS | | UOUS |
| | WET ETCHING | | PRESENT | PRESENT | PRESENT | PRESENT | ABSENT | ABSENT |
| EVALUATION | RESIDUAL IMPURITY | Si | 1.2E+12 | 2.5E+11 | 5.4E+10 | 5.4E+10 | 4.5E+11 | N.D. |
| RESULTS | SURFACE DENSITY | | | | | | | (4.7E+9) |
| | (atoms/cm²) | C | 5.0E+10 | 3.3E+10 | N.D. | N.D. | N.D. | N.D. |

Fourth Embodiment

In this embodiment, testing as in the third embodiment is carried out while changing the ratio of the amount of gas flowing.

The surface cleaning treatment conditions at the second growth interface 104 with the same sample structure as in FIG. 1, the amount of TBCl supplied as etching gas is 19.4 μmol/min (corresponding to an InP etching rate of 20.5 nm/min), the amount of PH₃ supplied is fixed at 68 mmol/min, the amount of TMIn supplied changes between 0 to 30 μmol/min, and cleaning treatment of the surface is carried out for ten minutes so as to grow the undoped InP layer 105. Continuing on, the concentration of residual Si of the second interface is investigated using SIMS analysis.

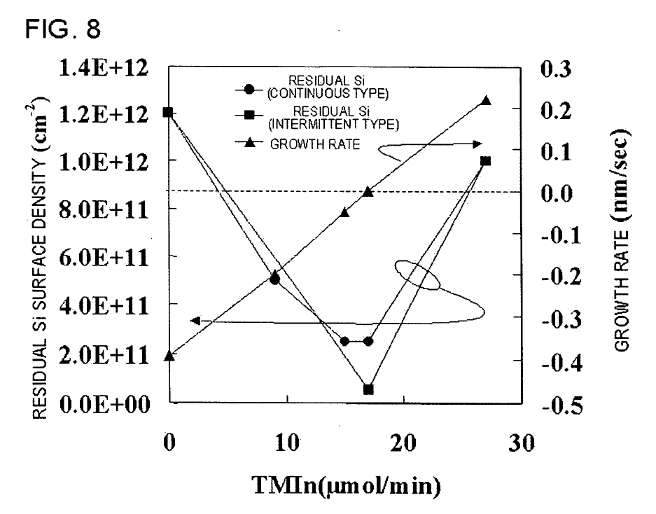

FIG. 8 shows change in the quantity of TMIn flowing for sample 2 in the third embodiment (shown as “residual Si (continuous type)” in the drawings), and the change in the amount of TMIn flowing for the sample 3 in the third embodiment (shown as “residual Si (intermittent type)” in the drawings).

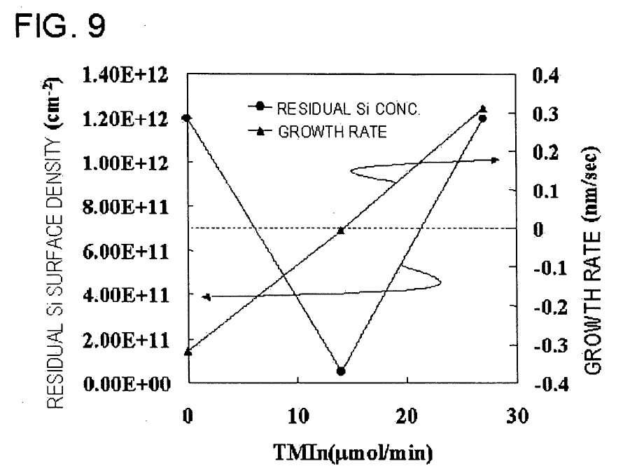

FIG. 9 shows change in the amount of TMIn flowing for the sample 4 in the third embodiment.

In FIG. 8 and FIG. 9, the surface density of the residual Si and the rate of growth of InP due to TBCl and TMIn (i.e. the rate of change of film thickness of the undoped InP layer 103 (first semiconductor layer)) are shown as positive, and the etching is shown as negative.

In either system, the quantity of TMIn supplied and the residual Si concentration reduce, and in the vicinity of a growth rate of 0 nm/sec, the residual Si concentration is shown to be a minimum, while when the quantity of TMIn flowing is increased, the concentration of the residual Si rises again. This is because, in the case of supplying only TBCl of the etching gas to the second growth interface 104, Si—Cl bonds of the residual Si of the surface that become temporarily detached from the surface as volatile silicon chloride (SiClₓ) are weak compared to Si—P bonds. The Si—Cl bonds are therefore soon broken and would become reattached to the surface. However, when TMIn is supplied at the same time as the TBCl, at the same time as the Si detaches from the surface as SiClₓ, In is buried at the stable group III site occupied up to this time by the Si, so that Si that has become temporarily detached from the surface cannot become reattached to the InP surface, and remains detached from the surface. The Si detachment efficiency is therefore at a maximum when the InP etching rate due to the TBCl and the InP growth rate due to the TMIn are exactly the same. When the InP growth rate due to the TMIn is greater than the etching rate of the InP due to the TBCl, in this case, prior to the Si becoming detached, an InP layer will be grown, and the concentration of residual Si at the second growth interface 104 will increase due to the cleaning treatment of the surface not being carried out.

From the results of FIG. 8 and FIG. 9, in the event that the rate of change of layer thickness is 0.1 nm/sec or less, an in particular in the case where there is substantially no change in layer thickness, it can be discerned that there is a marked reduction in the concentration of residual Si.

Fifth Embodiment

As shown in FIG. 11, the optical semiconductor device of this embodiment has a Double Channel Planar Buried Hetero Structure (DC-PBH) that is completed by forming a crystal growth process three times. Namely, first, a wave guide having a recombination layer spaced by grooves 5 μm wide is formed by growing a 2 μm wide wave guide layer composed of a double hetero structure including an InGaAsP Multiple Quantum Well (MQW) active layer 502 on an n-type InP substrate 500, by dry etching or wet chemical-etching a wave guide layer subjected to desired patterning via photolithographic processes employing an SiO₂ mask. Next, a second crystal growth process is implemented with just a SiO₂ film remaining on the wave guide, so that the wave guide is buried by a p-InP block layer 510 and an n-InP block layer 512. A regrowth interface at this time is referred to as a first regrowth interface 508. Next, dielectric film on a mesa including an MQW active layer is eliminated and a crystal growth process for a third time is implemented. A regrowth interface here is referred to as a second regrowth interface 506. In the third crystal growth process, directly before starting growth of the p-InP cladding layer 514, in a Metal Organic Vapor Phase Epitaxy (MOVPE) reactor, the TBCl constituting the etching gas, the TMIn and PH₃ constituting the growth source material, are supplied to such an extent that the etching rate and the growth rate are exactly the same to clean the second regrowth interface. The amount of TBCl supplied during this surface cleaning process is 19.4 μmol/min, which corresponds to an etching rate of 20.5 nm/min, the TMIn is supplied at 15.08 μmol/min, and the PH₃ is supplied at 2.68 mmol/min, with these corresponding to an InP growth rate of 20.5 nm/min. The etching rate for the InP due to TBCl and the InP growth rate due to the TMIn and PH₃ are therefore equal and there is no change at the InP layer grown up to the second crystal growth process during the surface cleaning treatment. Moreover, the cleaning treatment time can be changed between 0 seconds and ten minutes. After cleaning treatment, a p-InP cladding layer 514 and a p-type InGaAs contact layer 518 are grown. After this, the optical semiconductor device of the present invention is completed via a normal electrode forming process.

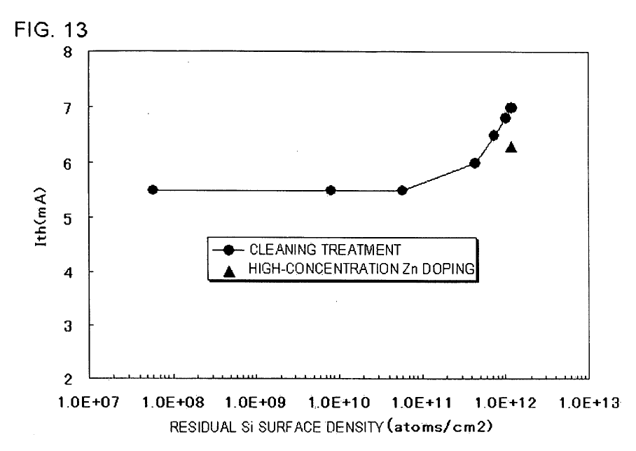

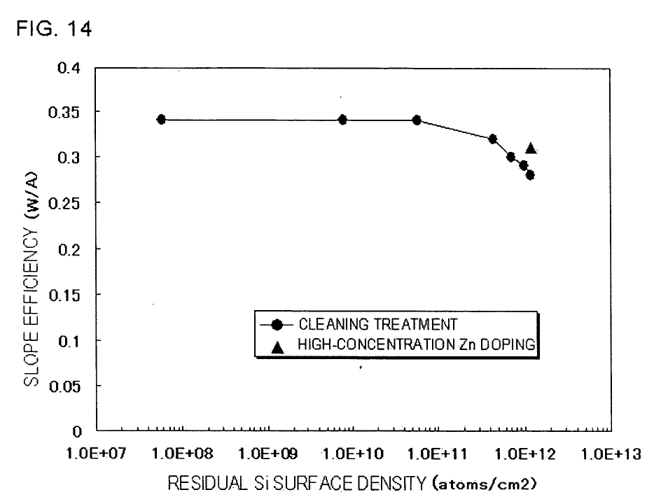

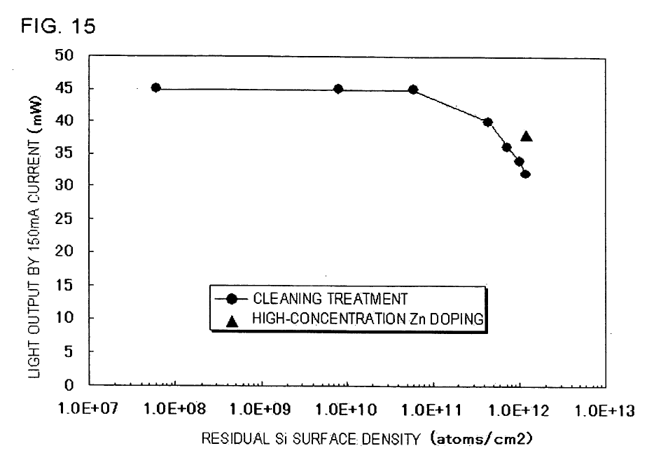

The 300 um-long cavity is formed by cleaving, and lasing characteristics are evaluated without coating at the facets. The results of this evaluation are shown in table 2. The surface density of the residual Si is the surface density of the residual Si occurring at the second regrowth interface analyzed by SIMS and the lower limit of Si detection in this measurement corresponds to 6×10⁷ atoms/cm². The surface density of the residual Si reduces with treatment time, and in 600 seconds falls below the lower limit of detection. The threshold current, slope efficiency, and optical output markedly improve in accompaniment with lower of the surface density of the residual Si. FIG. 13 is a view showing dependence on surface density of residual Si for current of a threshold value. Further, FIG. 14 is a view showing dependence of concentration of residual Si of the second regrowth interface for slope efficiency. Moreover, FIG. 15 is a view showing dependence of concentration of residual Si of the second regrowth interface for light output under the current injection of 150 mA. By making the surface density of the residual Si is approximately 1×10¹¹ cm⁻² or less, threshold current can be reduced by approximately 20% to 5.5 mA compared with the case where cleaning treatment is not performed. Further, the slope efficiency is improved by approximately 20% to 0.34 W/A and the light output power under the current injection of 150 mA increase by 1.4 times to 45 mW. For the purposes of comparison, a sample doped to 0.2 μm in the vicinity of the second growth interface with a high concentration of Zn of approximately 2×10¹⁸ cm⁻³ is also made using the technology disclosed in patent document 4 without using the cleaning treatment of the present invention. In this event, the threshold value, the slope efficiency, and the light output power under 150 mA current injection are 6.3 mA, 0.31 W/A, and 38 mW, respectivly, which is not sufficient for an improvement in results, with it being confirmed that improved results are greater when the concentration of the residual Si falls below 5×10¹¹ cm⁻² due to cleaning treatment of the present invention. This may be considered to be because, in the technology of patent document 4, as a result of doping with surplus Zn in order to compensate for the influence of residual Si on n-type layer forming by doping with a high concentration of Zn, the Inter Valence Band Absorption (IVBA) increases, the Zn diffuses in the active layer, and the internal differential quantum efficiency (ηi) falls. With regards to this, with the optical semiconductor device of the present invention, the forming of an n-inverted layer is avoided by reduction of the surface residual Si concentration, without a high concentration doping of Zn. Increases in the IVBA and decreases in ηi are therefore not induced, and it is possible to suppress current leakage from directly above the active layer to the current block layer. This means that it is possible to substantially improve the threshold value, slope efficiency, and light output.

TABLE 2

| | DOPING | CLEANING | RESIDUAL Si | THRESHOLD | SLOPE | LIGHT OUTPUT |
|---|---|---|---|---|---|---|
| | LAYER | TREATMENT | SURFACE DENSITY | VALUE CURRENT | EFFICIENCY | (@150 mA) |
| SAMPLE | cm-3 | TIME (sec) | (atoms/cm2) | (mA) | (W/A) | (mW) |
| LD-1 | N/A | 0 | 1.2E+12 | 7 | 0.28 | 32 |
| LD-2 | N/A | 10 | 1.0E+12 | 6.8 | 0.29 | 34 |
| LD-3 | N/A | 30 | 7.3E+11 | 6.5 | 0.3 | 36 |
| LD-4 | N/A | 60 | 4.4E+11 | 6 | 0.32 | 40 |
| LD-5 | N/A | 180 | 6.0E+10 | 5.5 | 0.34 | 45 |
| LD-6 | N/A | 300 | 8.1E+09 | 5.5 | 0.34 | 45 |
| LD-7 | N/A | 600 | 6.0E+07 | 5.5 | 0.34 | 45 |
| ref | 2 × 10¹⁸ | 0 | 1.20E+12 | 6.3 | 0.31 | 38 |

Sixth Embodiment

FIG. 12 is a structural view of an optical semiconductor integrated device of this embodiment. This optical semiconductor integrated device is a modulator integrated type DFB-LD completed via the fourth crystal growth process. Namely, first, a Double Hetero (DH) structure including an InGaAsP MQW active layer 601 is grown on an n-type lnP substrate 600 only formed with a diffraction grating at portions that are to constitute a semiconductor laser. Next, a mask is formed at a semiconductor laser section by a photolithographic process employing a dielectric mask etc. and a modulator portion is then etched by dry etching or wet chemical etching. Next, a DH structure containing a InGaAsP MQW layer 603 for modulator use is grown in the crystal growth of the second time. A regrowth interface at this time is referred to as a first regrowth interface 620.

Next, a mask is formed at a wave guide section and a modulator wave guide section for the semiconductor laser by a photolithographic process employing a dielectric mask, and the like again, portions other than the wave guide are then etched by dry etching or wet chemical etching.

After this, dielectric film remains only on the wave guide for semiconductor laser use and modulator use and a crystal growth process is implemented for a third time so as to grow a p-InP block layer 602 of a thickness of 0.1 μm and a p-type carrier concentration of 5×10¹⁷ cm⁻², a Semi-Insulating (SI)—InP block layer 604 of a thickness of 1.5 μm and a resistivity of 1×10⁹ Ωcm, and an n-InP block layer 606 of a thickness of 0.1 μm and an n-type carrier concentration of 3×10¹⁸ cm⁻³. A regrowth interface at this time is referred to as a second regrowth interface 644.

Next, the dielectric film on the wave guide for semiconductor laser use and modulator use is removed, and the fourth crystal growth process is implemented. This regrowth interface is referred to as a third regrowth interface. In the fourth crystal growth process, directly before starting growth of the p-InP cladding layer 608, in a MOVPE reactor, the TBCl constituting the etching gas, the TMIn and PH₃ constituting the growth source material, are supplied to such an extent that the etching rate and the growth rate are exactly the same to clean the second regrowth interface. The amount of TBCl supplied during this surface cleaning process is 19.4 μmol/min, which corresponds to an etching rate of 20.5 nm/min, the TMIn is supplied at 15.08 μmol/min, and the PH₃ is supplied at 2.68 mmol/min, with these corresponding to an InP growth rate of 20.5 nm/min. The etching rate for the InP due to TBCl and the InP growth etching rate due to the TMIn and PH₃ are therefore equal and there is no change at the InP layer grown up to the second crystal growth process during the surface cleaning treatment. The surface treatment time is taken to be ten minutes.

After cleaning treatment, a p-InP cladding layer 608 and a p-type contact layer 622 are grown. After this, the optical semiconductor device of the present invention is completed via a normal electrode forming process.

When comparing to a modulator integrated-type DFB-LD made without carrying out the surface treatment at the third regrowth interface for the purposes of comparison, at the modulator integrated-type DFB-LD implementing the surface treatment of the present invention, the concentration of the residual Si of the third regrowth interface is lower than the lower detection limit of the SIMS at equal to or less than 6×10⁷ atoms/cm². Therefore, in addition to the leakage current from directly above the semiconductor laser and modulator to the current block layer being extremely small, there is also very little current leaking between the semiconductor laser and the modulator. Further, doping of the vicinity of this regrowth interface with p-type dopant for surplus Zn etc. in order to cancel out the effect of residual Si is not necessary. There is also no increase in internal loss or reduction in internal differential quantum efficiency accompanying diffusion of p-type dopant at this semiconductor laser portion, and no uneven distribution of electric field strength accompanying diffusion of p-type dopant. As a result, in addition to improvements to the threshold value of approximately 10%, to the slope efficiency of 5%, and the output of 10%, an improvement in the results of approximately 20% is obtained for the 3 dB down frequency.

In the above, a description is given of the present invention based on the embodiments but the present invention is by no means limited to the embodiments, and various forms are possible within the scope of the technological idea of the present invention.

For example, in the above embodiment, bis(dimethylamino) phosphine chloride (BDMAPCl: [N(CH₃)₂]N₂PCl) is used as the source material having an etching action, but other Cl family source materials such as, for example, hydrogen chloride (HCl), and chloromethane (CH₃Cl), carbon tetrachloride (CCl₄), bis(dimethylamino) arsino-chloride ([N(CH₃)₂]₂AsCl), phosphorous trichloride (PCl₃), arsenic trichloride AsCl₃, chlorine (Cl₂), or similarly Br family source material, I family source material, or F family source material may also be used. In the case of using other source materials, the decomposition efficiency and the etching efficiency of the source material differs depending on the source material but fundamentally, as shown in the above embodiments, it is possible to maximize etching efficiency by balancing the etching rate of the semiconductor layer due to the etching source material and the growth rate of the semiconductor layer due to the crystal growth source material as shown in the aforementioned embodiments.

In the above embodiments, an example is described taking the case of using MOVPE techniques as crystal growth techniques but other growth techniques such as, for example, molecular beam epitaxy (MBE) techniques and gas source MBE (GSMBE) techniques, Metal Organic MBE (MOMBE) techniques, and Chemical Beam Epitaxy (CBE). In the above embodiment, a description is given of an InP family material but the present invention is by no means limited in this respect, and may also be applied to semiconductor materials such as other group III-V compound semiconductors such as GaAs, InAs, GaP, GaN etc., and group II-VI compound semiconductors, etc.

Further, 625 degree centigrade is given as the substrate temperature in the above embodiment but providing the temperature range is a temperature range in which normal crystal growth is possible, for example, in the case of InP, 400 to 700 degree centigrade, and in the case of GaAs, 400 to 800 degree centigrade, by compensating for changes in substrate temperature for etching rate for the semiconductor layer due to the etching source material and growth rate of the semiconductor layer due to crystal growth source material so that both are balanced, it is possible to attain maximum cleaning efficiency and attain similar results.

Further, in the above embodiment, the first gas containing etching agent having an etching action with respect to the semiconductor layer and the second gas containing crystal growth source material are supplied to the semiconductor layer surface at the same time but a method of providing these alternately is also possible. In this case, it is difficult to implement sufficient cleaning when the growth of the semiconductor layer progresses excessively and after the growth of the thickness of the layer advances by one to three atoms, it is preferable to rapidly switch over the growth gas and the etching base in such a manner that etching can be carried out.

Further, in the above embodiment, a description is given of an optical semiconductor integrated device of the present invention taking an example of a modulator integrated type DFB-LD where a DFB-LD and a modulator are combined but an integrated device such as a Fabry-Perot laser or FP-LD, DBR-LD, or semiconductor amplifier etc. is also effective. The number of devices integrated is also not limited to two, and the present invention is also effective in the case of integrating a large number of devices.

Moreover, in the above embodiment a description is given taking a Fabry-Perot laser of a DC-PBH structure as an example of an optical semiconductor device of the present invention but the use of semiconductor lasers of other structures and the use of other stand-alone active devices such as SOA and modulators etc. is also effective. In particular, in the case of using an active MMI-LD with a large active layer surface area, substantial effects are obtained such as the output saturation under the high current injection being suppressed, and the maximum light output being substantially improved, etc. In particular, the present invention is applicable to devices having an active MMI structure.

As described above, according to the present invention, inducing of the occurrence of impurity diffusion and crystal defects within the original semiconductor layer does not occur, changes in shape are kept to a minimum, and stable and reproducible elimination of impurity contamination and physical damage at a semiconductor substrate surface prior to crystal growth and a semiconductor surface prior to regrowth is possible. This contributes greatly to the improvement of performance of a semiconductor device having a growth interface.

1. A cleaning treatment method for eliminating contaminant adhered to the surface of a semiconductor layer, comprising:
a cleaning treatment step of simultaneously or alternately causing an etching agent having an etching action with respect to the semiconductor layer and crystal growth source material to come into contact with the semiconductor layer.

2. A cleaning treatment method for eliminating contaminant adhered to the surface of a semiconductor layer, comprising:
a cleaning treatment step of exposing the surface of the semiconductor layer to an atmosphere containing an etching agent having an etching action with respect to the semiconductor layer and crystal growth source material.

3. A cleaning treatment method for eliminating contaminant adhered to the surface of a semiconductor layer, comprising:
a cleaning treatment step of simultaneously providing a first gas including an etching agent having an etching action with respect to the semiconductor layer and a second gas including crystal growth source material to the surface of the semiconductor layer.

4. The cleaning treatment method according to claim 3, wherein the first gas and the second gas are supplied in an intermittent manner.

5. The cleaning treatment method according to claim 1, wherein a difference in layer thickness of the semiconductor layer before and after implementation of the cleaning treatment step is 100 nm or less.

6. The cleaning treatment method according to claim 1, wherein layer thickness of the semiconductor layer is not substantially reduced during implementation of the cleaning treatment step.

7. The cleaning treatment method according to claim 5, wherein change in layer thickness of the semiconductor layer is controlled by adjusting the quantitative ratio of the etching agent and the crystal growth source material.

8. The cleaning treatment method according to claim 3, wherein when it is taken that: a symbol for rate of change of layer thickness of the semiconductor layer is positive when layer thickness increases and is negative when layer thickness decreases;
rate of change of layer thickness of the semiconductor layer during implementation of the cleaning treatment step is R;
rate of change of layer thickness of the semiconductor layer in the case of supplying only the first gas to the semiconductor layer surface is r₁, and
rate of change of layer thickness of the semiconductor layer in the case of supplying only the second gas to the semiconductor layer surface is r₂,
the amount of the first gas and the second gas supplied is adjusted in such a manner that
an absolute value for the rate of change of layer thickness becomes:

|R|<|r₂|<|r₁|

9. The cleaning treatment method according to claim 8, wherein R<0.

10. The cleaning treatment method according to claim 8, wherein |R| is 0.1 nm/sec or less.

11. The cleaning treatment method according to claim 1, wherein the crystal growth source material includes an element constituting the semiconductor layer.

12. The cleaning treatment method according to claim 1, wherein the crystal growth source material includes organic metal.

13. The cleaning treatment method according to claim 1, wherein the etching agent is a halogen element or compound thereof.

14. The cleaning treatment method according to claim 1, wherein the semiconductor layer is comprised of compound semiconductor.

15. The cleaning treatment method according to claim 14, wherein the semiconductor layer is comprised of a group III-V compound semiconductor.

16. The cleaning treatment method according to claim 15, wherein the crystal growth source material is a compound including a group III element constituting the semiconductor layer.

17. The cleaning treatment method according to claim 15, wherein the group III element constituting the semiconductor layer is comprised of a single species.

18. The cleaning treatment method according to claim 15, wherein the group III element constituting the semiconductor layer is indium (In).

19. A method of manufacturing a semiconductor device comprising the steps of:
forming a first semiconductor layer at an upper part of a semiconductor substrate;
subjecting the surface of the first semiconductor layer to cleaning treatment; and
forming a second semiconductor layer on the first semiconductor layer,
wherein the step of subjecting the surface of the first semiconductor layer to cleaning treatment includes a step of causing an etching agent having an etching action with respect to the semiconductor layer and crystal growth source material to come into contact with the surface of the semiconductor layer.

20. A method of manufacturing a semiconductor device comprising the steps of:
forming a first semiconductor layer at an upper part of a semiconductor substrate;
subjecting the surface of the first semiconductor layer to cleaning treatment; and
forming a second semiconductor layer on the first semiconductor layer,
wherein the step of subjecting the surface of the first semiconductor layer to cleaning treatment includes a step of exposing the surface of the semiconductor layer to an atmosphere containing an etching agent having an etching action with respect to the semiconductor layer and crystal growth source material.

21. A method of manufacturing a semiconductor device comprising the steps of:
forming a first semiconductor layer at an upper part of a semiconductor substrate;
subjecting the surface of the first semiconductor layer to cleaning treatment; and
forming a second semiconductor layer on the first semiconductor layer,
wherein the step of subjecting the surface of the first semiconductor layer to cleaning treatment includes a step of simultaneously supplying a first gas including an etching agent having an etching action with respect to the semiconductor layer and a second gas including crystal growth source material to the surface of the semiconductor layer.

22. The method of manufacturing a semiconductor device according to claim 21, wherein the first gas and the second gas are supplied in an intermittent manner.

23. The method of manufacturing a semiconductor device according to claim 19, wherein a difference in layer thickness of the second semiconductor layer before and after implementation of the step of subjecting the surface of the first semiconductor layer to cleaning treatment is 100 nm or less.

24. The method of manufacturing a semiconductor device according to claim 19, wherein layer thickness of the second semiconductor layer is not substantially reduced during implementation of the step of subjecting the surface of the first semiconductor layer to cleaning treatment.

25. The method of manufacturing a semiconductor device according to claim 23, wherein change in layer thickness of the first semiconductor layer is controlled by adjusting the quantitative ratio of the etching agent and the crystal growth source material.

26. The method of manufacturing a semiconductor device according to claim 21, wherein when it is taken that:
a symbol for rate of change of layer thickness of the first semiconductor layer is positive when layer thickness increases and is negative when layer thickness decreases;
rate of change of layer thickness of the first semiconductor layer during implementation of the step of subjecting the surface of the first semiconductor layer to cleaning treatment is R;
rate of change of layer thickness of the first semiconductor layer in the case of supplying only the first gas to the first semiconductor layer surface is r1, and
rate of change of layer thickness of the first semiconductor layer in the case of supplying only the second gas to the first semiconductor layer surface is r2,
the amount of the first gas and the second gas supplied is adjusted in such a manner that
an absolute value for the rate of change of layer thickness becomes:

|R|<|r₂|<|r₁|

27. The method of manufacturing a semiconductor device according to claim 26, wherein R<0.

28. The method of manufacturing a semiconductor device according to claim 26, wherein |R| is 0.1 nm/sec or less.

29. The method of manufacturing a semiconductor device according to claim 19, wherein the crystal growth source material includes an element constituting the first semiconductor layer.

30. The method of manufacturing a semiconductor device according to claim 19, wherein the crystal growth source material includes a metal organic.

31. The method of manufacturing a semiconductor device according to claim 19, wherein the etching agent is a halogen element or compound thereof.

32. The method of manufacturing a semiconductor device according to claim 19, wherein the first semiconductor layer is comprised of compound semiconductor.

33. The method of manufacturing a semiconductor device according to claim 32, wherein the first semiconductor layer is comprised of compound semiconductor.

34. The method of manufacturing a semiconductor device according to claim 33, wherein the crystal growth source material includes a group III element constituting the first semiconductor layer.

35. The method of manufacturing a semiconductor device according to claim 34, wherein the group III element constituting the semiconductor layer is a single species.

36. The method of manufacturing a semiconductor device according to claim 35, wherein the group III element constituting the semiconductor layer is indium (In).

37. The method of manufacturing a semiconductor device according to claim 19, wherein the first semiconductor layer and the second semiconductor layer are formed using vapor phase epitaxy.

38. The method of manufacturing a semiconductor device according to claim 19, wherein a mask is formed on the first semiconductor layer after the step of forming the first semiconductor layer, and after eliminating the mask, the step of subjecting the surface of the first semiconductor layer to cleaning treatment is implemented.

39. An optical semiconductor device with a concentration of residual Si of a regrowth interface within a p-type semiconductor layer having a surface density of 5×10¹¹ atoms/cm² or less.

40. The optical semiconductor device according to claim 39, wherein the regrowth interface is an interface of a p-type current block layer and a layer connecting with a lower part of the p-type current block layer.

41. The optical semiconductor device according to claim 39, wherein the regrowth interface is an interface of a p-type cladding layer and a layer connecting with a lower part of the p-type cladding layer.

42. The optical semiconductor device according to claim 39, wherein the regrowth interface is a regrowth interface within a p-type cladding layer.

43. The optical semiconductor device according to claim 39, having an active MMI structure.

44. An optical semiconductor integrated device with a concentration of residual Si of a regrowth interface within a p-type semiconductor layer having a surface density of 5×10¹¹ atoms/cm² or less.

45. The optical semiconductor integrated device according to claim 44, wherein the regrowth interface is an interface of a p-type current block layer and a layer connecting with a lower part of the p-type current block layer.

46. The optical semiconductor integrated device according to claim 44, wherein the regrowth interface is an interface of a p-type cladding layer and a layer connecting with a lower part of the p-type cladding layer.

47. The optical semiconductor integrated device according to claim 44, wherein the regrowth interface is a regrowth interface within a p-type cladding layer.

48. The optical semiconductor integrated device according to claim 44, further having an active MMI structure.
